(19) United States
(12) Patent Application Publication
(10) Pub. No.: US 2026/0194944 A1
(43) Pub. Date: Jul. 9, 2026

(54) ADAPTIVE THERMAL DESIGN POWER

(71) Applicant: Dell Products L.P., Round Rock, TX (US)

(72) Inventors: Troy Allen TIRITILLI, Round Rock, TX (US); Carlos Guillermo HENRY, Georgetown, TX (US); Rui AN, Austin, TX (US)

(73) Assignee: Dell Products L.P., Round Rock, TX (US)

(21) Appl. No.: 19/010,718

(22) Filed: Jan. 6, 2025

(51) Int. Cl. G06F 1/20; G06F 1/18; H05K 7/20

(52) U.S. Cl. CPC G06F 1/206; G06F 1/186; H05K 7/20172; H05K 7/20209

(57) ABSTRACT

An information handling system may include at least one processor and a plurality of slots operable to accept corresponding information handling resources. The information handling system may be configured to: determine, for each slot, a maximum amount of airflow associated with the slot; determine, for each slot, an air inlet temperature associated with the slot; based on the maximum amount of airflow and the air inlet temperature, determine a corresponding maximum thermal design power (TDP) that can be supported by each slot, wherein the maximum TDP is received from a power budget table (PBT); and transmit a command to the information handling resource in each slot setting its TDP to the determined maximum TDP.

### TECHNICAL FIELD

The present disclosure relates in general to information handling systems, and more particularly to temperature and power management of information handling resources such as graphics processing units (GPUS).

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems may include one or more accelerators such as GPUs. For example, Peripheral Component Interconnect Express (PCIe) GPUs plug into standard PCIe slots. Other GPUs may use other form factors.

PCIe cards are designed to meet specifications for various thermal parameters including, as examples, thermal qualification temperature, maximum operating temperature, hardware slowdown temperature, hardware shutdown temperature, thermal design power (TDP), etc. Server-class systems in data centers and other large scale compute environments may include a management controller such as a baseboard management controller (BMC), that utilizes a data structure commonly referred to as power budge table (PBT) to provide thermal and power consumption management for PCIe resources.

The TDP of newer GPUs may exceed the thermal capacity of the information handling system, resulting in performance limitations. While a system might have sufficient electrical support for such GPUs, thermal constraints such as adapter temperature, airflow, and air inlet temperature may nevertheless restrict their full utilization. In existing implementations, static TDP settings are used, which do not account for varying thermal conditions across different types of information handling system or different locations (e.g., different PCIe slots) within a given information handling system. As a result, GPUs may run at the lowest load that the system's thermal capacity can support, preventing them from achieving their full performance potential.

Embodiments of this disclosure improve on this situation by dynamically adjusting the TDP settings for a given GPU based on real-time device topology discovery. For example, a predefined look up table and corresponding equations may be based on device thermal specifications which are captured within the PBT and may be managed from a management controller.

It should be noted that while the example of GPUs is discussed in detail herein, embodiments may also be used for other types of information handling resources.

It should be noted that the discussion of a technique in the Background section of this disclosure does not constitute an admission of prior-art status. No such admissions are made herein, unless clearly and unambiguously identified as such.

### SUMMARY

In accordance with the teachings of the present disclosure, the disadvantages and problems associated with thermal design power for information handling resources may be reduced or eliminated.

In accordance with embodiments of the present disclosure, an information handling system may include at least one processor and a plurality of slots operable to accept corresponding information handling resources. The information handling system may be configured to: determine, for each slot, a maximum amount of airflow associated with the slot; determine, for each slot, an air inlet temperature associated with the slot; based on the maximum amount of airflow and the air inlet temperature, determine a corresponding maximum thermal design power (TDP) that can be supported by each slot, wherein the maximum TDP is received from a power budget table (PBT); and transmit a command to the information handling resource in each slot setting its TDP to the determined maximum TDP.

In accordance with these and other embodiments of the present disclosure, a method may include an information handling system that includes a plurality of slots operable to accept corresponding information handling resources determining, for each slot, a maximum amount of airflow associated with the slot; the information handling system determining, for each slot, an air inlet temperature associated with the slot; based on the maximum amount of airflow and the air inlet temperature, the information handling system determining a corresponding maximum thermal design power (TDP) that can be supported by each slot, wherein the maximum TDP is received from a power budget table (PBT); and the information handling system transmitting a command to the information handling resource in each slot setting its TDP to the determined maximum TDP.

In accordance with these and other embodiments of the present disclosure, an article of manufacture may include a non-transitory, computer-readable medium having computer-executable instructions thereon that are executable by a processor of an information handling system that includes a plurality of slots operable to accept corresponding information handling resources for: determining, for each slot, a maximum amount of airflow associated with the slot; determining, for each slot, an air inlet temperature associated with the slot; based on the maximum amount of airflow and the air inlet temperature, determining a corresponding maximum thermal design power (TDP) that can be supported by each slot, wherein the maximum TDP is received from a power budget table (PBT); and transmitting a command to the information handling resource in each slot setting its TDP to the determined maximum TDP.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure; and

FIG. 2 illustrates an example method, in accordance with embodiments of the present disclosure.

### DETAILED DESCRIPTION

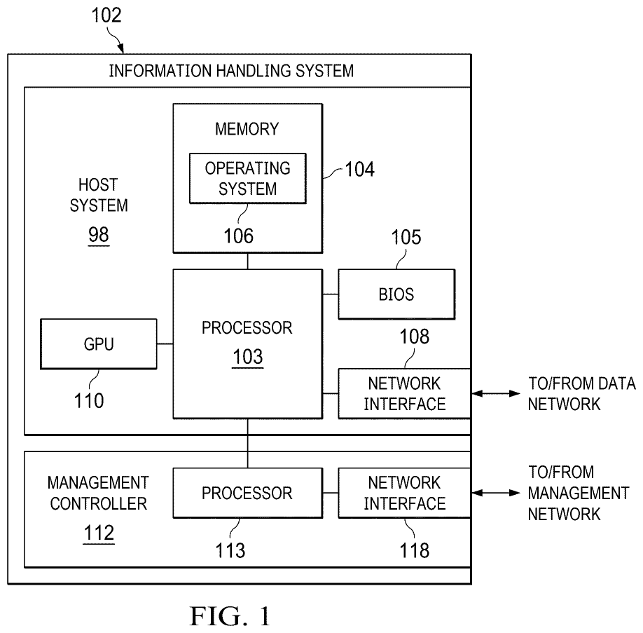

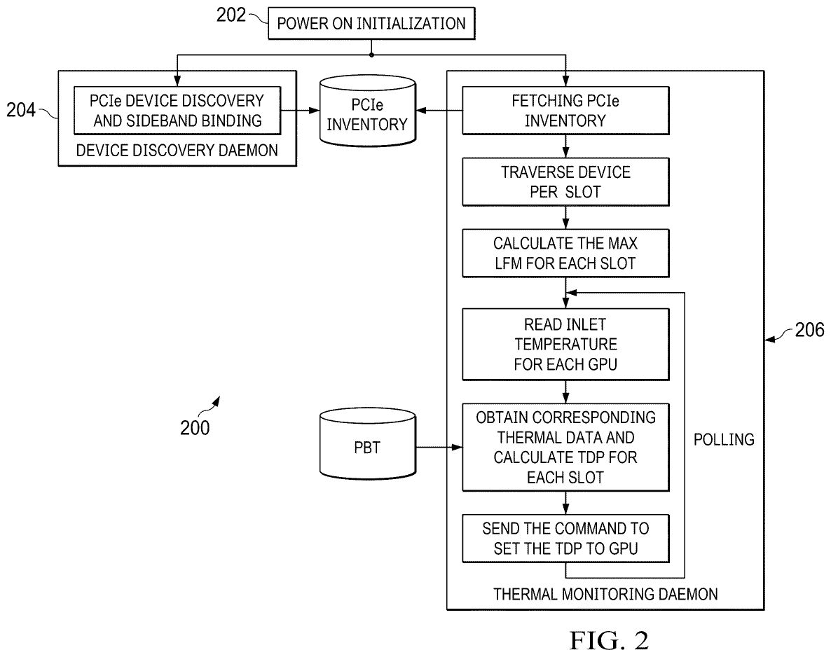

Preferred embodiments and their advantages are best understood by reference to FIGS. 1 and 2, wherein like numbers are used to indicate like and corresponding parts.

For the purposes of this disclosure, the term “information handling system” may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”) or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

For purposes of this disclosure, when two or more elements are referred to as “coupled” to one another, such term indicates that such two or more elements are in electronic communication or mechanical communication, as applicable, whether connected directly or indirectly, with or without intervening elements.

When two or more elements are referred to as “coupleable” to one another, such term indicates that they are capable of being coupled together.

For the purposes of this disclosure, the term non-“computer-readable medium” (e.g., transitory or transitory computer-readable medium) may include any instrumentality or aggregation of instrumentalities that may and/or retain data instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; communications media such as wires, optical fibers, microwaves, radio waves, and other electromagnetic and/or optical carriers; and/or any combination of the foregoing.

For the purposes of this disclosure, the term “information handling resource” may broadly refer to any component system, device, or apparatus of an information handling system, including without limitation processors, service processors, basic input/output systems, buses, memories, I/O devices and/or interfaces, storage resources, network interfaces, motherboards, and/or any other components and/or elements of an information handling system.

For the purposes of this disclosure, the term “management controller” may broadly refer to an information handling system that provides management functionality (typically out-of-band management functionality) to one or more other information handling systems. In some embodiments, a management controller may be (or may be an integral part of) a service processor, a baseboard management controller (BMC), a chassis management controller (CMC), or a remote access controller (e.g., a Dell Remote Access Controller (DRAC) or Integrated Dell Remote Access Controller (iDRAC)).

FIG. 1 illustrates a block diagram of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data (which may generally be referred to as “physical storage resources”). As shown in FIG. 1, information handling system 102 may comprise a processor 103, a memory 104 communicatively coupled to processor 103, a BIOS 105 (e.g., a UEFI BIOS) communicatively coupled to processor 103, a network interface 108 communicatively coupled to processor 103, and a management controller 112 communicatively coupled to processor 103.

In operation, processor 103, memory 104, BIOS 105, and network interface 108 may comprise at least a portion of a host system 98 of information handling system 102. In addition to the elements explicitly shown and described, information handling system 102 may include one or more other information handling resources.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may include any system, device, or apparatus configured to retain program instructions and/or data for a period of time (e.g., computer-readable media). Memory 104 may include RAM, EEPROM, a PCMCIA card, flash memory, magnetic storage, opto-magnetic storage, or any suitable selection and/or array of volatile or non-volatile memory that retains data after power to information handling system 102 is turned off.

As shown in FIG. 1, memory 104 may have stored thereon an operating system 106. Operating system 106 may comprise any program of executable instructions for aggregation of programs of executable instructions) configured to manage and/or control the allocation and usage of hardware resources such as memory, processor time, disk space, and input and output devices, and provide an interface between such hardware resources and application programs hosted by operating system 106. In addition, operating system 106 may include all or a portion of a network stack for network communication via a network interface (e.g., network interface 108 for communication over a data network). Although operating system 106 is shown in FIG. 1 as stored in memory 104, in some embodiments operating system 106 may be stored in storage media accessible to processor 103, and active portions of operating system 106 may be transferred from such storage media to memory 104 for execution by processor 103.

Network interface 108 may comprise one or more suitable systems, apparatuses, or devices operable to serve as an interface between information handling system 102 and one or more other information handling systems via an in-band network. Network interface 108 may enable information handling system 102 to communicate using any suitable transmission protocol and/or standard. In these and other embodiments, network interface 108 may comprise a network interface card, or “NIC.” In these and other embodiments, network interface 108 may be enabled as a local area network (LAN)-on-motherboard (LOM) card.

Management controller 112 may be configured to provide management functionality for the management of information handling system 102. Such management may be made by management controller 112 even if information handling system 102 and/or host system 98 are powered off or powered to a standby state. Management controller 112 may include a processor 113, memory, and a network interface 118 separate from and physically isolated from network interface 108.

As shown in FIG. 1, processor 113 of management controller 112 may be communicatively coupled to processor 103. Such coupling may be via a Universal Serial Bus (USB), System Management Bus (SMBus), and/or one or more other communications channels.

Network interface 118 may be coupled to a management network, which may be separate from and physically isolated from the data network as shown. Network interface 118 of management controller 112 may comprise any suitable system, apparatus, or device operable to serve as an interface between management controller 112 and one or more other information handling systems via an out-of-band management network. Network interface 118 may enable management controller 112 to communicate using any suitable transmission protocol and/or standard. In these and other embodiments, network interface 118 may comprise a network interface card, or “NIC.” Network interface 118 may be the same type of device as network interface 108, or in other embodiments it may be a device of a different type.

Information handling system 102 may also include one or more GPUS 110. As discussed above, embodiments of this disclosure may be used to manage the power consumption and thermal properties of GPUs 110.

As discussed herein, embodiments may rely on a PBT, which is a data structure that contains data and/or equations for performing TDP calculations, among other things. For example, the PBT may include a data table or an equation relating thermal resistance (e.g., in degrees Celsius per Watt) of a given type of GPU to its air inlet temperature. The PBT may also include a data table or equation relating the maximum power that can be supported in a given slot to that slot's airflow, the air inlet temperature, and the thermal resistance of the card in that slot. The PBT may define such information for different models of information handling system, for different slots within a given model, and for different types of card within a given slot.

The implementation details of the PBT will vary from one implementation to another, but for the sake of concreteness, an example for a particular slot of a particular information handling system is shown below at Table 1.

TABLE 1

| Maximum | | Thermal | Maximum |
|---|---|---|---|
| Airflow | Air Inlet | Resistance | Power |
| (LFM) | Temperature | (C/W) | Supported |
| 1000 | 45 | .0707 | 651 |
| 1000 | 40 | .0707 | 721 |
| 1000 | 35 | .0707 | 792 |
| 800 | 45 | .0762 | 603 |
| 800 | 40 | .0762 | 669 |
| 800 | 35 | .0762 | 735 |
| 600 | 45 | .0840 | 548 |
| 600 | 40 | .0840 | 607 |
| 600 | 35 | .0840 | 667 |
| 400 | 45 | .0963 | 478 |
| 400 | 40 | .0963 | 530 |
| 400 | 35 | .0963 | 582 |
| 200 | 45 | .1216 | 378 |
| 200 | 40 | .1216 | 419 |
| 200 | 30 | .1216 | 461 |

Turning now to FIG. 2, an example method 200 illustrating one embodiment is shown. At step 202, the information handling system may perform power on initialization. At step 204, a device discovery daemon may execute on the system's management controller. This daemon may discover device information using PCIe inventory and sideband topology (e.g., using an I2C connection). The results may be stored in a PCIe inventory data structure in a shared memory region that is accessible to other daemons executing on the management controller.

At step 206, the management controller may execute a thermal monitoring daemon. The thermal monitoring daemon may fetch the PCIe inventory from shared memory. It may then iterate through each slot, calculating the maximum airflow (e.g., in linear feet per minute (LFM)) that can be supplied by the air movers (e.g., fans) in proximity to that slot.

The thermal monitoring daemon may then enter a polling loop, in which it monitors the inlet temperature for each slot's GPU based on a temperature sensor and adjusts the TDP for the GPU accordingly. For example, once the daemon has determined the current inlet temperature for each slot, it may retrieve from the PBT correlating those data temperatures (as well as the maximum airflows for the slots and the thermal resistances for the cards in the slots) to the maximum supported power dissipation that can be cooled.

Thus the thermal monitoring daemon may periodically (e.g., once per second, once per minute, or at any desired frequency) determine, for each slot, the real-time TDP that can be supported in that slot. The daemon may then send a command to each GPU resetting its TDP to the determined value.

By customizing the TDP levels to match the current conditions of each slot, the system can optimize GPU performance while avoiding thermal overheating.

One of ordinary skill in the art with the benefit of disclosure understand this will that the preferred initialization point for the method depicted in FIG. 2 and the order of the steps comprising that method may depend on the implementation chosen. In these and other embodiments, the method may be implemented as hardware, firmware, software, applications, functions, libraries, or other instructions. Further, FIGURE although 2 discloses a particular number of steps to be taken with respect to the disclosed method, the method may be executed with greater or fewer steps than depicted. The method may be implemented using any of the various components disclosed herein (such as the components of FIG. 1), and/or any other system operable to implement the method.

Accordingly, embodiments of this disclosure may provide many benefits. For example, by customizing TDP levels to match real-time conditions, embodiments may ensure that GPUs operate at their maximum potential without risking thermal issues. Embodiments may adapt to various server configurations and changes in PCIe device topology, making it versatile enough to handle environments. Further, by proactively managing thermal conditions, embodiments may reduce the risk of hardware failures, leading to lower maintenance costs and improved reliability.

This disclosure encompasses all changes, substitutions, variations, alterations, and modifications to the exemplary embodiments herein that a person having ordinary skill in the art would comprehend. Similarly, where appropriate, the appended claims encompass all changes, substitutions, variations, alterations, and modifications to the exemplary embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

Further, reciting in the appended claims that a structure is “configured to” or “operable to” perform one or more tasks is expressly intended not to invoke 35 U.S.C. § 112 (f) for that claim element. Accordingly, none of the claims in this application as filed are intended to be interpreted as having means-plus-function elements. Should Applicant wish to invoke § 112 (f) during prosecution, Applicant will recite claim elements using the “means for [performing a function]” construct.

All examples and conditional language recited herein are intended for pedagogical objects to aid the reader in understanding the invention and the concepts contributed by the inventor to furthering the art, and are construed as being without limitation to such specifically recited examples and conditions. Although embodiments of the present inventions have been described in detail, it should be understood that various changes, substitutions, and alterations could be made hereto without departing from the spirit and scope of the disclosure.

What is claimed is:

1. An information handling system comprising:
at least one processor; and
a plurality of slots operable to accept corresponding information handling resources;
wherein the information handling system is configured to:
determine, for each slot, a maximum amount of airflow associated with the slot;
determine, for each slot, an air inlet temperature associated with the slot;
based on the maximum amount of airflow and the air inlet temperature, determine a corresponding maximum thermal design power (TDP) that can be supported by each slot, wherein the maximum TDP is received from a power budget table (PBT); and
transmit a command to the information handling resource in each slot setting its TDP to the determined maximum TDP.

2. The information handling system of claim 1, wherein the information handling resources are graphics processing units (GPUS).

3. The information handling system of claim 2, wherein the GPUs are Peripheral Component Interconnect Express (PCIe) GPUs.

4. The information handling system of claim 1, wherein the transmitting the command is carried out by a management controller of the information handling system.

5. The information handling system of claim 4, wherein the management controller is a baseboard management controller (BMC).

6. The information handling system of claim 1, wherein the information handling system is configured to determine, for each slot, a thermal resistance associated with the information handling resource in that slot;
wherein the maximum TDP is further based on the thermal resistance.

7. A method comprising:
an information handling system that includes a plurality of slots operable to accept corresponding information handling resources determining, for each slot, a maximum amount of airflow associated with the slot;
the information handling system determining, for each slot, an air inlet temperature associated with the slot;
based on the maximum amount of airflow and the air inlet temperature, the information handling system determining a corresponding maximum thermal design power (TDP) that can be supported by each slot, wherein the maximum TDP is received from a power budget table (PBT); and
the information handling system transmitting a command to the information handling resource in each slot setting its TDP to the determined maximum TDP.

8. The method of claim 7, wherein the information handling resources are graphics processing units (GPUS).

9. The method of claim 8, wherein the GPUs are Peripheral Component Interconnect Express (PCIe) GPUs.

10. The method of claim 7, wherein the transmitting the command is carried out by a management controller of the information handling system.

11. The method of claim 10, wherein the management controller is a baseboard management controller (BMC).

12. The method of claim 7, further comprising the information handling system determining, for each slot, a thermal resistance associated with the information handling resource in that slot;
wherein the maximum TDP is further based on the thermal resistance.

13. An article of manufacture comprising a non-transitory, computer-readable medium having computer-executable instructions thereon that are executable by a processor of an information handling system that includes a plurality of slots operable to accept corresponding information handling resources for:
determining, for each slot, a maximum amount of airflow associated with the slot;
determining, for each slot, an air inlet temperature associated with the slot;
based on the maximum amount of airflow and the air inlet temperature, determining a corresponding maximum thermal design power (TDP) that can be supported by each slot, wherein the maximum TDP is received from a power budget table (PBT); and
transmitting a command to the information handling resource in each slot setting its TDP to the determined maximum TDP.

14. The article of manufacture of claim 13, wherein the information handling resources are graphics processing units (GPUS).

15. The article of manufacture of claim 14, wherein the GPUs are Peripheral Component Interconnect Express (PCIe) GPUs.

16. The article of manufacture of claim 13, wherein the transmitting the command is carried out by a management controller of the information handling system.

17. The article of manufacture of claim 16, wherein the management controller is a baseboard management controller (BMC).

18. The article of manufacture of claim 13, wherein the information handling system is configured to determine, for each slot, a thermal resistance associated with the information handling resource in that slot; and
wherein the maximum TDP is further based on the thermal resistance.
